(19) United States
(12) Patent Application Publication
(10) Pub. No.: US 2025/0379572 A1
(43) Pub. Date: Dec. 11, 2025

(54) TIME MODULATION FOR DC-DC ANALOG CURRENT SENSING

(71) Applicant: STMicroelectronics International N.V., Geneva (CH)

(72) Inventors: Sandor PETENYI, Lysa nad Labem (CZ) (CZ); Lukas BURYANEC, Trutnov (CZ)

(73) Assignee: STMicroelectronics International N.V., Geneva (CH)

(21) Appl. No.: 19/311,287

(22) Filed: Aug. 27, 2025

Related U.S. Application Data
(63) Continuation of application No. 18/240,585, filed on Aug. 31, 2023, now Pat. No. 12,413,221.

(51) Int. Cl. H03K 17/082; H03K 5/24

(52) U.S. Cl. CPC H03K 17/082; H03K 5/24

(57) ABSTRACT

A current sensing circuit for switching converters provides accurate output current measurement without directly sensing output current. The circuit includes a replica switching element that conducts synchronously with a main switching element. A feedback circuit generates a replica voltage proportional to voltage drop across the main switching element during conduction. This replica voltage is modulated using a control signal having duty cycle proportional to ratio of input voltage to output voltage. An output filter processes the modulated replica voltage to generate sense voltage directly proportional to output current. The feedback circuit utilizes an operational amplifier and controllable transistor to maintain accurate voltage replication. The modulation circuit employs complementary switches controlled by duty cycle signal. A corresponding method replicates drain-to-source voltage of the main switching transistor, maintains the replicated voltage through feedback control, modulates it with appropriate duty cycle, and filters the result to obtain DC voltage proportional to output current.

### RELATED APPLICATION

This application is a continuation of U.S. application For patent Ser. No. 18/240,585, filed Aug. 31, 2023, the content of which is incorporated by reference in its entirety.

### TECHNICAL FIELD

This disclosure pertains to continuous-time input and output current sensing in a DC-DC converter, such as in an inverting buck-boost converter utilized for producing a negative rail voltage in a display panel.

### BACKGROUND

Power management is an aspect of concern in modern electronic systems, especially in portable devices such as smartphones, tablets, and laptops. These devices rely on efficient and precise voltage regulation to optimize power consumption and prolong battery life. One significant power-consuming component in such devices is its display panel. Display technologies, such as liquid crystal displays (LCDs) and organic light-emitting diodes (OLEDs), require accurate control of input and output currents to ensure optimal performance, brightness, and energy efficiency.

DC-DC converters, such as buck-boost converters, are often used in power management integrated circuits (PMICs) to regulate the voltage supplied to the display panel. In a typical PMIC, the converter generates and regulates positive and negative rail voltages based on an input voltage. The display panel consumes power by drawing input and output currents from these rails. Accurate determination and control of these currents is of interest for maintaining optimal display performance, energy efficiency, and prolonging battery life.

Traditional methods of monitoring and controlling the operation of DC-DC converters involve directly measuring the drain-to-source voltage (VDS) of the high-side transistor, which can be challenging and may introduce inaccuracies in the control loop. Furthermore, determining the display input current often involves complex circuitry, increasing complexity and reducing reliability. There is a need for an improved method and apparatus for determining input and output currents to the display panel and controlling the operation of DC-DC converters with enhanced accuracy and minimal complexity. In particular, measuring the output current through the negative rail is of interest. Given this, further development into this area is needed.

### SUMMARY

A current sensing circuit for a switching converter includes a replica switching element configured to conduct synchronously with a main switching element, a feedback circuit configured to generate a replica voltage proportional to a voltage drop across the main switching element during conduction, a modulation circuit configured to modulate the replica voltage with a control signal having a duty cycle proportional to a ratio of input voltage to output voltage of the converter, and an output filter configured to generate a sense voltage from the modulated replica voltage, wherein the sense voltage is proportional to an output current of the converter.

The feedback circuit may include a first resistor coupled between an input voltage terminal and a first node, a second resistor coupled between the input voltage terminal and a second node, an operational amplifier having a first input coupled to the first node and a second input coupled to the second node, and a controllable transistor having a control terminal coupled to an output of the operational amplifier, wherein the controllable transistor is configured to conduct a current through a third resistor to generate the replica voltage.

In some embodiments, the replica switching element may be coupled between the first node and a switching node, and the operational amplifier may be configured to maintain the voltage at the second node equal to the voltage at the first node through feedback control of the controllable transistor.

The controllable transistor may optionally be a p-channel transistor and the third resistor may be coupled between a drain of the p-channel transistor and a reference potential.

The modulation circuit may include a first switch configured to selectively connect the replica voltage to the output filter when the control signal is in a first state, and a second switch configured to selectively connect an input of the output filter to a reference potential when the control signal is in a second state.

The first and second switches may operate in complementary fashion.

The current sensing circuit may further include an averaging filter coupled between the feedback circuit and the modulation circuit, the averaging filter configured to generate an average value of the replica voltage.

The averaging filter may include a series resistor and a shunt capacitor configured to average the replica voltage.

The current sensing circuit may further include a buffer amplifier coupled between the feedback circuit and the modulation circuit.

The control signal may be generated by a control signal generator that includes a ramp generator configured to generate a ramp signal having a slope dependent on the output voltage, and a comparator configured to compare the ramp signal with a reference voltage dependent on the input voltage.

The ramp generator may include a voltage-to-current converter configured to convert a voltage proportional to the output voltage into a charging current, and a capacitor charged by the charging current to generate the ramp signal.

The output filter may include a series resistance and a shunt capacitance configured to extract a DC component from the modulated replica voltage.

A method for sensing output current in a switching power converter without directly measuring the output current includes replicating a drain-to-source voltage of a main switching transistor using a replica transistor that switches synchronously with the main switching transistor, maintaining the replicated voltage using a feedback amplifier circuit, modulating the replicated voltage with a duty cycle equal to a ratio of input voltage to output voltage of the converter, and filtering the modulated voltage to obtain a DC voltage directly proportional to the output current.

Replicating the drain-to-source voltage may include coupling the replica transistor in series with a pull-up resistor between an input voltage and a switching node, applying a same gate control signal to both the replica transistor and the main switching transistor, and sensing a voltage at a node between the pull-up resistor and the replica transistor.

Maintaining the replicated voltage may include comparing the sensed voltage with a reference voltage using an operational amplifier, controlling a current source transistor with an output of the operational amplifier, and conducting current through a sense resistor via the current source transistor to generate the replicated voltage.

The method may further include coupling a second pull-up resistor between the input voltage and the current source transistor, and configuring the operational amplifier to maintain equal voltages at the replica transistor node and the current source transistor node.

The method may further include averaging the replicated voltage before the modulating to obtain an average value representative of input current to the converter.

Averaging may include passing the replicated voltage through a low-pass filter.

Modulating the replicated voltage may include connecting the replicated voltage to an output node when a control signal having the duty cycle is asserted, and connecting the output node to ground when the control signal is deasserted.

The method may further include generating the control signal by generating a ramp signal with a slope proportional to the output voltage, comparing the ramp signal with a reference voltage proportional to the input voltage, and outputting the control signal based on the comparison.

Generating the ramp signal may include converting a voltage proportional to the output voltage to a charging current, mirroring the charging current using a current mirror, and charging a capacitor with the mirrored current to generate the ramp signal.

### BRIEF DESCRIPTION OF THE DRAWINGS

FIG. 1 is a block diagram of a display system described herein.

FIG. 2 is a schematic of the inverting buck-boost converter described herein.

FIG. 2A is a schematic of an alternative embodiment of the inverting buck-boost converter described herein.

FIG. 3 is a schematic of a control signal generator that generates the control signals for the switches of the inverting buck-boost converter of FIG. 2.

FIG. 4 is a graph showing generation of the control signals of FIG. 3 during operation.

FIG. 5 is a schematic of another alternative embodiment of the inverting buck-boost converter described herein.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Note that in the following description, any resistor or resistance mentioned is a discrete device, unless stated otherwise, and is not simply an electrical lead between two points. Therefore, any resistor or resistance connected between two points has a higher resistance than a lead between those two points, and such resistor or resistance cannot be interpreted as a lead. Similarly, any capacitor or capacitance mentioned is a discrete device, unless stated otherwise, and is not a parasitic element, unless stated otherwise. Additionally, any inductor or inductance mentioned is a discrete device, unless stated otherwise, and is not a parasitic element, unless stated otherwise.

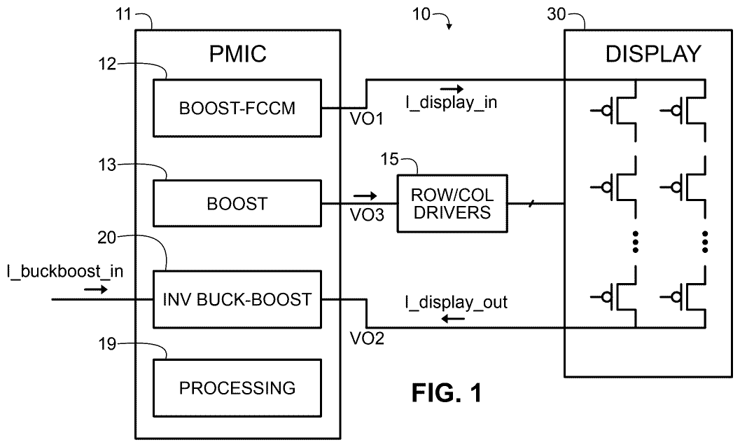

Referring first to FIG. 1, a display system 10 includes an Active Matrix Organic Light Emitting Diode (AMOLED) display panel 30 powered between a positive rail VO1 and a negative rail VOT2. A power management integrated circuit (PMIC) 11 features a boost-fixed frequency continuous mode (boost-FCCM) converter 12 designed to generate and regulate the positive rail voltage VO1. The PMIC 11 also includes an inverting buck-boost converter 20 employed to generate and regulate the negative rail voltage VO2.

The PMIC 11 further includes a boost converter 13 that generates a regulated pre-drive voltage VO3, which is utilized by row and column drivers 15. These drivers 15 are utilized for activating and deactivating display elements within the AMOLED display panel 30. The input current, denoted as I_display_in, flows out of the boost-FCCM converter 12, through the positive rail VO1, and into the display panel 30. The output current, denoted I_display_out, flows out of the display panel 30 through the negative rail VO2 and into the inverting buck-boost converter 20, which in this instance is configured to act as a current sink. As will be explained in greater detail below, the inverting buck-boost converter 20 receives an input current I_buckboost_in and, based thereupon, sinks the output current I_display_out from the display.

The objective is to estimate the display output current I_display_out by measuring the input current to the buck-boost converter I_buckboost_in, rather than measuring the display input current I_display_in from the boost-FCCM converter 12. From the display output current I_display_out, the display input current I_display_in can be calculated by considering the display as a resistance.

Using the relationship:

$$\frac{Iout}{Iin} = \frac{Vin}{Vout} ,$$

and keeping in mind that the display output current I_display_out is the output current of (e.g., the current sunk by) the inverting buck-boost converter 20, the display output current I_display_out can be calculated by a processing circuit 19 within the PMIC 11 as:

$$I\_display \_out = \frac{Vin}{VO 2} \times I\_buckboost \_in .$$

From the display output current I_display_out, the display input current I_display_in can be calculated by the processing circuit 19.

Therefore, the determination of the input current to the buck boost converter I_buckboost_in is to be performed, as will be described below.

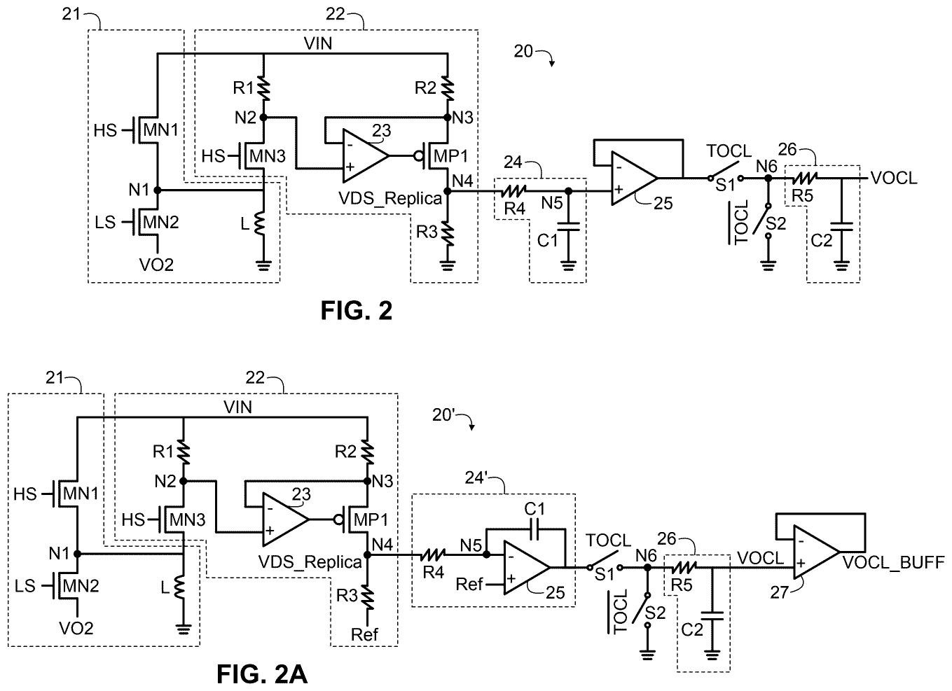

The inverting buck-boost converter 20 is described in more detail with reference to FIG. 2. The converter 20 comprises an inverting buck-boost circuit 21, which is coupled between an input voltage VIN and the negative rail VO2. Additionally, a sensing circuit 22 is coupled to the output of the inverting buck-boost circuit 21. A filter 24 is implemented at the output of the sensing circuit 22, and the output of the filter 24 connects to the input of an amplifier 25, configured as a unity gain buffer. A first switch S1 selectively connects the output of the buffer 25 to an output filter 26 in response to a control signal TOCL which has a duty cycle proportional to Vin/VO2, while a second switch S2 selectively connects the junction between switch S1 and the output filter 26 to the ground in response to the inverse T̅O̅C̅L̅ of the control signal TOCL.

Examining the inverting buck-boost circuit 21 in further detail, it includes a first n-channel transistor MN1 with its drain connected to the input voltage VIN, its source connected to node N1, and its gate receiving a high side control signal HS. The circuit 21 also features a second n-channel transistor MN2 with its drain connected to node N1, its source connected to the negative rail VO2, and its gate receiving a low side control signal LS. An inductor L is connected between node N1 and ground.

As to the sensing circuit 22, it comprises a resistor R1 connected between the input voltage VIN and node N2, as well as an n-channel transistor MN3 connected between nodes N2 and N1. Specifically, the drain of MN3 is connected to node N2, the source of MN3 is connected to node N1, and the gate of MN3 receives the high side control signal HS. A resistor R2 is connected between the input voltage VIN and node N3. A p-channel transistor MP1 has its source connected to node N3, its drain connected to node N4, and its gate connected to receive the output of an amplifier 23. A resistor R3 is connected between node N4 and ground. The amplifier 23 has its non-inverting input terminal connected to node N2, its inverting input terminal connected to node N3, and its output connected to the gate of the p-channel transistor MP1. The filter 24 is formed by a resistor R4 connected between node N4 and node N5, and a capacitor C1 connected between node N5 and ground.

The buffer 25 is formed by an amplifier having its non-inverting input terminal connected to node N5, its output connected to switch S1, and its inverting input terminal connected to its output.

The switch S1 is connected between the output of the amplifier 25 and node N6, and, as previously mentioned, is controlled by the control signal TOCL. The switch S2 is connected between node N6 and ground, and, as stated, is controlled by the inverse TOCL of the control signal TOCL.

Lastly, the output filter 26 is formed by a resistor R5 connected between node N6 and a first terminal of capacitor C2, while a second terminal of the capacitor C2 is connected to ground.

Alternative versions of the inverting buck-boost converter 20 exist. For example, in the version of the inverting buck-boost converter 20′ shown in FIG. 2A, the filter 24 and amplifier 25 may be rearranged as a non-inverting operation amplifier integrator 24′, with the inverting input terminal of the amplifier 25 being connected to node N5, capacitor C1 being connected between the inverting input terminal and the output of the amplifier 25, and non-inverting input terminal of the amplifier 25 being coupled to a reference voltage. In addition, here, resistor R3 is connected between node N4 and the reference voltage. Also, as an example, the sense voltage VOCL generated by the output filter 26 is here buffered by an amplifier 27 configured as a unity gain buffer, but it should be understood that this buffering arrangement may be added to any embodiment of the inverting buck-boost converter 20.

Operation is as follows. The inverting buck-boost converter 20, which is part of the PMIC 11, operates in two modes, buck and boost, to generate and regulate the negative rail voltage VO2 based on the input voltage VIN. In the buck mode, the input voltage VIN is stepped down, while in the boost mode, it is stepped up. This is achieved by controlling the switching of transistors MN1 and MN2 using the high side control signal HS and low side control signal LS, which in turn regulates the flow of current through the inductor L for energy storage and release, ultimately generating the negative rail voltage VO2.

The sensing circuit 22 creates a replica of the drain-to-source voltage (Vds) of the high-side transistor MN1, called VDS_Replica, through a combination of components and a feedback mechanism. Transistor MN3 is a replica of transistor MN1. Here, transistor MN3 acts as a switch. During high side conduction when transistors MN1 and MN3 are on, since the resistance of resistor R1 is much greater than the on-resistance of MN3, it may be assumed that node N2 is at the same voltage as node N1 when MN3 is on, but is otherwise at VIN due to the resistor R1 acting as a pull-up. The sensing circuit 22 uses amplifier 23 to maintain equal voltages at nodes N2 and N3. The feedback mechanism involving amplifier 23 and transistor MP1 adjusts the gate voltage of MP1, maintaining the voltage across resistor R2 at node N3 as being equal to the voltage across resistor R1 at node N2. Consequently, the voltage at node N4, VDS_Replica, is proportional to the drain-to-source voltage Vds of transistor MN1.

Observe that the combination of resistors R1, R2, and R3 creates a voltage division that scales the voltage at node N4 to match the actual VDS of MN1, allowing the sensing circuit to accurately replicate the drain-to-source voltage VDS of transistor MN1. Through the generation of VDS_Replica therefore, this design enables precise monitoring and control of the operation of the inverting buck-boost converter 20 without directly measuring the drain-to-source voltage of the high-side transistor MN1.

Continuing with the description of operation, VDS_Replica as generated at node N4 passes through the filter 24. This results in a voltage representative of the input current I_buckboost_in being generated at the non-inverting input terminal to the amplifier 25, and, after buffering, this voltage is sent to the output filter 26 through the switch circuits S1, S2.

Switch S1 operates synchronously with the control signal TOCL, which, as stated, has a duty cycle proportional to Vin/VO2. When TOCL is high, switch S1 closes, connecting the output of amplifier 25 to node N6. Conversely, when TOCL is low, switch S1 opens, disconnecting the buffer from node N6. Simultaneously, switch S2 operates synchronously with the inverse of the control signal TOCL, denoted as T̅O̅C̅L̅. When T̅O̅C̅L̅ is high, switch S2 closes, connecting node N6 to ground, and when T̅O̅C̅L̅ is low, switch S2 opens, disconnecting node N6 from ground.

This synchronized operation of switches S1 and S2, combined with the duty cycle of TOCL, creates a pulse-width modulated (PWM) signal at node N6, with the pulse width being proportional to Vin/VO2. This PWM signal then passes through output filter 26, which filters out high-frequency components, generating the sense voltage VOCL.

Since the duty cycle of TOCL is proportional to Vin/VO2 and the voltage at the non-inverting input terminal of amplifier 25 represents the input current I_buckboost_in, the sense voltage VOCL produced at the output of output filter 26 is proportional to the absolute value of the display output current I_display_out. Therefore, at this point, the display output current I_display_out can be calculated by the processing circuit 19 as:

$${I}_{{display}_{out}} = \frac{Vin}{VO 2} \times {I}_{{buckboost}_{i n}} = I\_buckboost \_out$$

This calculation will now be fully explained. At node N4, the instantaneous voltage across transistor MN1 is:

$${V}_{N 4} = VDS\_Replica ( t ) = {RON}_{MN 1} \cdot {I}_{L} ( t )$$

Here, V_{N4} is the voltage at node N4, RON_{MN1} is the on-resistance of transistor MN1, and I_{L}(t) is the current through inductor L.

Filter 24′ averages its input signal. In this way, at node N5, there is the average value of node N4, represented as:

$${V}_{N 5} = \overline{{V}_{N 4} ( t )}$$

Here, V_{N5} is the voltage at node N5. Since RON_{MN1} is almost constant, the equations can be rewritten as:

$${V}_{N 5} = \overline{{V}_{N 4} ( t )} = \overline{{RON}_{M N 1} \cdot {I}_{M N 1} ( t )} = {RON}_{M N 1} \cdot \overline{{I}_{M N 1} ( t )}$$

Therefore, the voltage V_{N5} includes information about the average current in the transistor MN1, which is also the input current for the inverting buck-boost 20. Therefore:

$${V}_{N 5} = {RON}_{M N 1} \cdot \overline{{I}_{M N 1} ( t )} = {RON}_{M N 1} \cdot I\_buckboost \_in$$

Due to the action of switches S1 and S2, and filter 26, the following operation is effective performed:

$${V}_{N 5} \cdot Vin / V O 2$$

It is possible to write:

$$VOCL = {V}_{N 5} \cdot \frac{Vin}{V O 2} = {RON}_{M N 1} \cdot I\_buckboost \_in \cdot Vin / VO 2$$

Recalling, however, that:

$$I\_buckboost \_in \cdot Vin = I\_buckboost \_out \cdot VO 2$$

It can be said that:

$$VOCL = {RON}_{M N 1} \cdot {I}_{{buckboost}_{i n}} \cdot \frac{V i n}{VO 2} = {RON}_{M N 1} \cdot I\_buckboost \_out$$

Therefore, it is possible to state that:

$$VOCL = {RON}_{M N 1} \cdot I\_buckboost \_out = {RON}_{M N 1} \cdot I\_display \_out$$

$$Therefore ,$$

$${I}_{{display}_{out}} = I\_buckboost \_out$$

Continuing with the description of operation, tn order to determine the display input current I_display_in from the display output current I_display_out, the resistance of the current path through the display 30 is taken into account. The display panel 30 can be thought of as a resistive element through which the input current I_display_in flows, causing a voltage drop across it. This voltage drop is equal to the difference between the positive rail voltage VO1 and the negative rail voltage VO2.

According to Ohm's Law, the voltage across a resistive element is equal to the product of the current flowing through it and its resistance (V=I×R). In this case, the voltage across the display panel 30 can be expressed as the product of the display input current I_display_in and the resistance R_display of the current path through the display, which can be represented as:

$$VO 1 - VO 2 = I\_display \_in \times R\_display$$

Given that the display output current I_display_out is now known, as is the relationship between the display input and output currents, the above equation can be rearranged to find the display input current I_display_in:

$${I}_{display \_ in} = \frac{VO 1 - VO 2}{R\_display} = I\_buckboost \_out$$

By knowing the resistance R_display of the current path through the display, the display input current I_display_in can be calculated by the processing circuit 19 using the voltage difference between the positive rail VO1 and the negative rail VO2. This approach allows for the determination of the display input current I_display_in and therefore I_buckboost_out based on the previously calculated display output current I_display_out and the known resistance of the display panel 30.

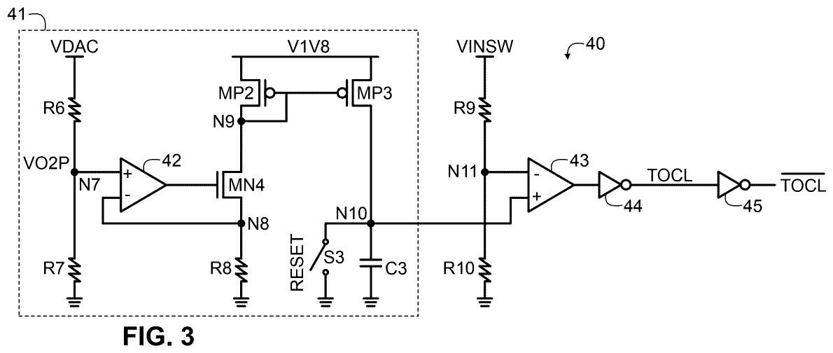

The control signal TOCL and its inverse T̅O̅C̅L̅ are generated by a control signal generator 40, described in further detail with reference to FIG. 3. The control signal generator 40 includes a ramp generator 41 and a comparator circuit 43.

The ramp generator 41 includes a resistor R6 connected between voltage VDAC and node N7, and a resistor R7 connected between node N7 and ground. An amplifier 42 has its non-inverting input terminal connected to node N7, its inverting input terminal connected to node N8, and its output connected to the gate of n-channel transistor MN4. The drain of MN4 is connected to node N9, while its source is connected to node N8. A resistor R8 is connected between node N8 and ground. A current mirror is connected between nodes N9 and N10, and is formed by p-channel transistor MP2, which has its source connected to voltage V1V8, its drain connected to node N9, and its gate connected to node N9. The current mirror also includes a p-channel transistor MP3 with its source connected to voltage V1V8, its drain connected to node N10, and its gate connected to node N9. A switch S3 selectively connects node N10 to ground and is controlled by a reset signal RESET. A capacitor C3 is connected between node N10 and ground.

The comparator circuit 43 comprises an amplifier 43 configured as a comparator, with its non-inverting input terminal connected to node N10, its inverting input terminal connected to node N11, and its output connected to the input of inverter 44. A resistor R9 is connected between a voltage VINSW and node N11. An inverter 45 has its input connected to the output of inverter 44.

In operation, the ramp generator 41 creates a ramp signal at node N10 by charging and discharging capacitor C3 through a current mirror formed by transistors MP2 and MP3. In greater detail, the operation of amplifier 42 and transistor MN4 converts voltage VO2P (which is proportional to the negative rail voltage VO2) to a current flowing in the left-side of the current mirror. When switch S3 is opened by deassertion of the reset signal, the mirrored current flowing in the right-side of the current mirror charges capacitor C3, with the rate of charge and the slope of the ramp being set by the value of the mirrored current and the capacitance of the capacitor C3.

The amplifier 43, configured as a comparator, compares the ramp signal at node N10 with the reference voltage at node N11 and outputs a high or low signal depending on whether the ramp signal is above or below the voltage at node N11. This output signal is then sent to the input of inverter 44, which inverts the signal to generate the control signal TOCL. Finally, the control signal TOCL is inverted once more by inverter 45 to produce the inverse TOCL of the control signal TOCL.

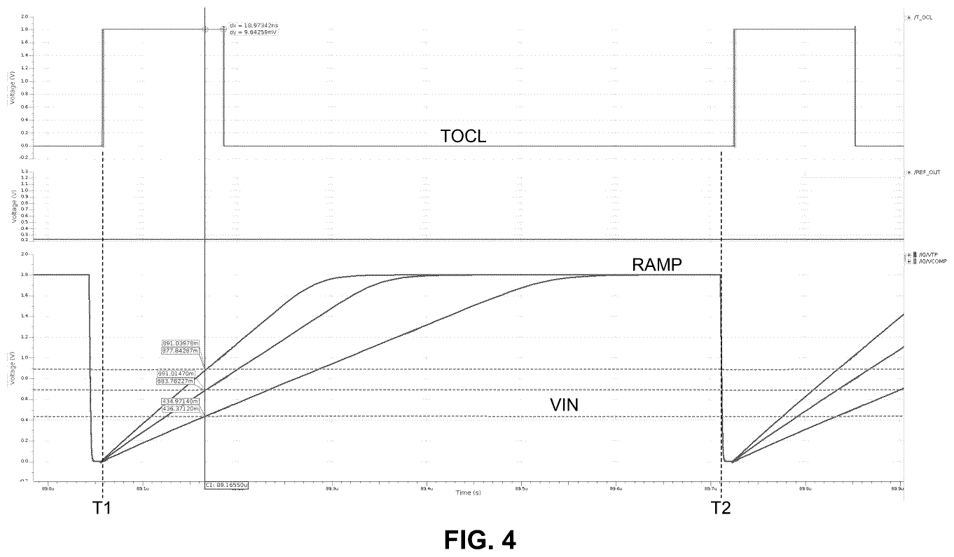

The generation of TOCL and the ramp signal at node N10 (denoted RAMP) can be seen in FIG. 4. Just prior to time T1, the reset signal RESET has been asserted, closing switch S3, causing discharge of the charge on capacitor C3 to ground. Therefore at time T1, RAMP is at ground. This means that RAMP is less than the reference voltage at node N11, resulting in deassertion of the output of the amplifier 43, and therefore assertion of the control signal TOCL.

The reset signal RESET is then deasserted and RAMP begins to ramp upwardly as described above. Observe that the ramping rate of RAMP changes depending upon the value of the input voltage VIN because the mirrored current magnitude of dependent on the voltage VO2P. At time T2, RAMP has exceeded the reference voltage at node N11, with the result being that the output of the amplifier 43 is asserted and therefore the control signal TOCL is deasserted, as shown at time T2.

The sensing circuit described above can be utilized with other types of converters apart from an inverting buck-boost converter. For instance, non-inverting buck-boost converters, Cuk converters, or other DC-DC converters that involve precise control and regulation of output voltages could benefit from the inventive approach. A notable aspect described above is the ability to determine the display output current by measuring the input current to the converter and calculating the display input current accordingly. This principle can be applied to any converter that serves as a current sink and is used in conjunction with a display panel, or any other load that can be considered as a resistive element.

The overall advantages are numerous. Firstly, the sensing circuit described herein allows for precise control and monitoring of the converter's operation without directly measuring high-side transistor drain-to-source voltage, which can be challenging and may introduce inaccuracies in the control loop. By generating a replica of this voltage and utilizing the control signal (TOCL) as generated, the accurate control and regulation of the converter's output voltage is achieved.

Secondly, the sensing circuit simplifies the process of determining the display input current by permitting calculation of it from the display output current and known resistance of the display panel. This approach eliminates the need for direct measurement of the display input current, reducing complexity and increasing reliability. By enabling precise control and regulation of output voltages, the efficiency and performance of display systems can be improved, leading to better energy management, longer battery life, and enhanced user experiences.

Lastly, this approach is versatile and can be applied to various types of converters and power management systems. For example, the approach may be applied to a buck converter, a non-inverting buck-boost controller, or a boost controller.

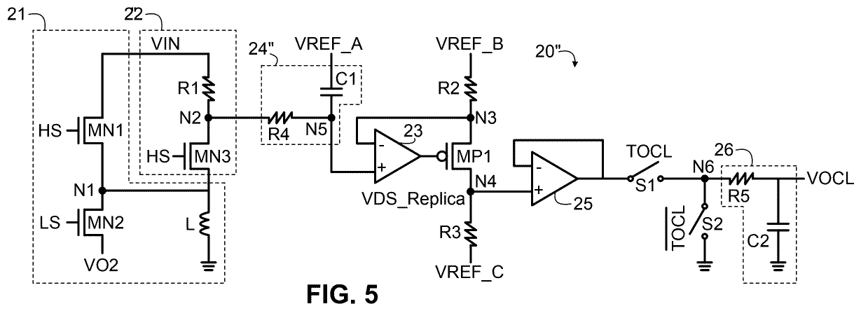

Finally, it is evident that modifications and variations can be made to what has been described and illustrated herein without departing from the scope of this disclosure. For example, refer now to the embodiment of the inverting buck-boost converter 20″ shown in FIG. 5. Here, the filter 24″ formed by resistor R1 and C1 has been placed before the amplifier 23, with resistor R4 being connected between nodes N2 and N5, capacitor C1 being connected between node N5 and a reference voltage VREF_A, and the non-inverting input terminal of amplifier 23 being connected to node N5. In addition, the resistor R2 is connected between node N3 and a reference voltage VREF_B to provide offset and the resistor R3 is connected between node N4 and a reference voltage VREF_C. The reference voltages VREF_A and VREF_B may be equal. Operation of this inverting buck-boost converter 20″ is otherwise as described above.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A current sensing circuit for a switching converter, comprising:
a replica switching element configured to conduct synchronously with a main switching element of the switching converter;
a feedback circuit configured to generate a replica voltage proportional to a voltage drop across the main switching element;
a modulation circuit configured to modulate the replica voltage with a control signal having a duty cycle proportional to a ratio of input voltage to output voltage of the switching converter; and
an output filter configured to generate a sense voltage from the modulated replica voltage, wherein the sense voltage is proportional to an output current of the switching converter.

2. The current sensing circuit of claim 1, wherein the feedback circuit comprises:
a first resistor coupled between an input voltage terminal and a first node;
a second resistor coupled between the input voltage terminal and a second node;
an operational amplifier having a first input coupled to the first node and a second input coupled to the second node;
a controllable transistor having a control terminal coupled to an output of the operational amplifier, wherein the controllable transistor is configured to conduct a current through a third resistor to generate the replica voltage.

3. The current sensing circuit of claim 2, wherein:
the replica switching element is coupled between the first node and a switching node; and
the operational amplifier is configured to maintain the voltage at the second node equal to the voltage at the first node through feedback control of the controllable transistor.

4. The current sensing circuit of claim 2, wherein the controllable transistor is a p-channel transistor and the third resistor is coupled between a drain of the p-channel transistor and a reference potential.

5. The current sensing circuit of claim 1, wherein the modulation circuit comprises:
a first switch configured to selectively connect the replica voltage to the output filter when the control signal is in a first state; and
a second switch configured to selectively connect an input of the output filter to a reference potential when the control signal is in a second state.

6. The current sensing circuit of claim 5, wherein the first and second switches operate in complementary fashion.

7. The current sensing circuit of claim 1, further comprising an averaging filter coupled between the feedback circuit and the modulation circuit, the averaging filter configured to generate an average value of the replica voltage.

8. The current sensing circuit of claim 7, wherein the averaging filter comprises:
a series resistor; and
a shunt capacitor configured to average the replica voltage.

9. The current sensing circuit of claim 1, further comprising a buffer amplifier coupled between the feedback circuit and the modulation circuit.

10. The current sensing circuit of claim 1, wherein the control signal is generated by a control signal generator comprising:
a ramp generator configured to generate a ramp signal having a slope dependent on the output voltage; and
a comparator configured to compare the ramp signal with a reference voltage dependent on the input voltage.

11. The current sensing circuit of claim 10, wherein the ramp generator comprises:
a voltage-to-current converter configured to convert a voltage proportional to the output voltage into a charging current; and
a capacitor charged by the charging current to generate the ramp signal.

12. The current sensing circuit of claim 1, wherein the output filter comprises:
a series resistance; and
a shunt capacitance configured to extract a DC component from the modulated replica voltage.

13. A method for sensing output current in a switching converter without directly measuring the output current, comprising:
replicating a drain-to-source voltage of a main switching transistor of the switching converter using a replica transistor that switches synchronously with the main switching transistor;
maintaining the replicated voltage using a feedback amplifier circuit;
modulating the replicated voltage with a duty cycle equal to a ratio of input voltage to output voltage of the converter to generate a modulated voltage; and
filtering the modulated voltage to obtain a DC voltage directly proportional to the output current.

14. The method of claim 13, wherein replicating the drain-to-source voltage comprises:
coupling the replica transistor in series with a pull-up resistor between an input voltage and a switching node;
applying a same gate control signal to both the replica transistor and the main switching transistor; and
sensing a voltage at a node between the pull-up resistor and the replica transistor.

15. The method of claim 14, wherein maintaining the replicated voltage comprises:
comparing the sensed voltage with a reference voltage using an operational amplifier;
controlling a current source transistor with an output of the operational amplifier; and
conducting current through a sense resistor via the current source transistor to generate the replicated voltage.

16. The method of claim 15, further comprising:
coupling a second pull-up resistor between the input voltage and the current source transistor; and
configuring the operational amplifier to maintain equal voltages at the replica transistor node and the current source transistor node.

17. The method of claim 13, further comprising averaging the replicated voltage before the modulating to obtain an average value representative of input current to the converter.

18. The method of claim 17, wherein averaging comprises passing the replicated voltage through a low-pass filter.

19. The method of claim 13, wherein modulating the replicated voltage comprises:
connecting the replicated voltage to an output node when a control signal having the duty cycle is asserted; and
connecting the output node to ground when the control signal is deasserted.

20. The method of claim 19, further comprising generating the control signal by:
generating a ramp signal with a slope proportional to the output voltage;
comparing the ramp signal with a reference voltage proportional to the input voltage; and
outputting the control signal based on the comparison.

21. The method of claim 20, wherein generating the ramp signal comprises:
converting a voltage proportional to the output voltage to a charging current;
mirroring the charging current using a current mirror; and
charging a capacitor with the mirrored current to generate the ramp signal.
